(19) United States
(12) Patent Application Publication
(10) Pub. No.: US 2016/0118533 A1
(43) Pub. Date: Apr. 28, 2016

(54) METHOD OF MANUFACTURING NANOSTRUCTURE SEMICONDUCTOR LIGHT EMITTING DEVICE

(71) Applicant: Samsung Electronics Co., Ltd., Suwon-si (KR)

(72) Inventors: MISAICHI TAKEUCHI, Hwaseong-si (KR); Sam Mook KANG, Hwaseong-si (KR); Shigeru INOUE, Yongin-si (KR); Ki Se KIM, Suwon-si (KR)

(21) Appl. No.: 14/887,466

(22) Filed: Oct. 20, 2015

(30) Foreign Application Priority Data
Oct. 28, 2014 (KR) 10-2014-0146874

(51) Int. Cl. H01L 33/00; H01L 33/24; H01L 33/06

(52) U.S. Cl. CPC H01L 33/0075; H01L 33/0025; H01L 33/06; H01L 33/24

(57) ABSTRACT

A method of manufacturing a nanostructure semiconductor light emitting device may include: stacking a mask layer on a conductive base layer and forming a through hole penetrating the mask layer; growing a nanocore through the through hole from the conductive base layer using precursor gas including indium-containing precursor gas in a mixed gas atmosphere of nitrogen and hydrogen; removing the mask layer; and sequentially growing an active layer and a first conductivity type semiconductor layer on a surface of the nanocore.

### CROSS-REFERENCE TO RELATED APPLICATION

This application claims priority under 35 U.S.C. §119 to Korean Patent Application No. 10-2014-0146874 filed on Oct. 28, 2014, with the Korean Intellectual Property Office, the disclosure of which is incorporated herein by reference.

### BACKGROUND

The present inventive concepts relate to methods of manufacturing a nanostructure semiconductor light emitting device.

Lately, as a novel type of semiconductor light emitting device technology, semiconductor light emitting devices employing a nanostructure have been developed. In semiconductor light emitting devices employing such nanostructures (hereinafter, referred to as “nanostructure semiconductor light emitting devices”), since crystallinity may be improved and an active layer may be obtained from a non-polar plane or a semi-polar plane, a deterioration in efficiency due to polarization may be reduced or prevented. In addition, since light may be emitted through a wide surface area, luminous efficiency may be improved. In order to effectively maintain such improved luminous efficiency, it maybe advantageous to further improve light extraction efficiency of nanostructure semiconductor light emitting devices.

### SUMMARY

An aspect of the present inventive concepts may provide a nanostructure semiconductor light emitting device having improved light extraction efficiency.

According to an aspect of the present inventive concepts, a method of manufacturing a nanostructure semiconductor light emitting device may include: stacking a mask layer on a conductive base layer and forming a through hole penetrating the mask layer, growing a nanocore through the through hole from the conductive base layer using a precursor gas including an indium-containing precursor gas in an atmosphere of mixed gas of nitrogen and hydrogen, removing the mask layer, and sequentially growing an active layer and a first conductivity type semiconductor layer on a surface of the nanocore.

A temperature in the growth of the nanocore may be equal to or greater than 800° C. and equal to or lower than 1050° C.

A volume rate of the mixture gas of nitrogen and hydrogen is 1:0.01 to 1:0.03.

The mask layer may include a first mask layer disposed on the conductive base layer and a second mask layer disposed on the first mask layer, a thickness of the second mask layer being greater than a thickness of the first mask layer.

An etch selectivity of the first mask layers is different from an etch selectivity of the second mask layers.

A flow rate of the indium-containing precursor gas may be gradually increased.

A flow rate of the indium-containing precursor gas may be gradually decreased.

The conductive base layer may be a second conductivity type semiconductor layer.

The nanocore may be InₓGa₁₋ₓN (0<x<1).

An amount of indium within the nanocore may increase in an upward direction.

An amount of indium within the nanocore may decrease in an upward direction.

The active layer may be a single quantum well layer or a multiple quantum well layer formed of In_{y}GaN_{1-y}/GaN or In_{y}GaN_{1-y}/In_{z}GaN_{1-z} (0<y<1, 0<z<1, y>z).

The indium-containing precursor gas may be trimethylindium (TMI) gas.

The conductive base layer may be an n-type GaN layer and the first conductivity type semiconductor layer may be a p-type GaN layer.

According to another aspect of the present inventive concepts, a method of manufacturing a nanostructure semiconductor light emitting device may include: stacking a mask layer on a conductive base layer and forming a through hole penetrating the mask layer, growing a superlattice nanocore through the through hole from the conductive base layer by alternately repeating a process of growing first nanocores formed of InₓGa₁₋ₓN (0≦x<1) and a process of growing second nanocores formed of In_{y}Ga_{1-y}N (0≦y≦1), using a precursor gas including trimethylindium (TMI) gas in an atmosphere of mixed gas of nitrogen and hydrogen, wherein y≠x, removing the mask layer, and sequentially growing an active layer and a first conductivity type semiconductor layer on a surface of the superlattice nanocore.

According to another aspect of the present inventive concepts, a method of manufacturing a nanocore of a nanostructure may include: providing a mixed gas atmosphere of nitrogen and hydrogen; and introducing an indium-containing precursor gas to the mixed gas atmosphere to grow a nanocore through a hole in a conductive base layer.

A volume rate of the mixture gas atmosphere of nitrogen and hydrogen is 1:0.01 to 1:0.03.

The nanocore may be grown at a temperature of 800° C. to 1050° C.

The nanocore may have a superlattice structure.

The nanocore may have a composition of InxGa1−xN (0<x<1) or AlxInyGa1−x−yN (0≦x≦1, 0<y<1, 0<x+y≦1) .

### BRIEF DESCRIPTION OF DRAWINGS

The above and other aspects, features and advantages of the present inventive concepts will be more clearly understood from the following detailed description taken in conjunction with the accompanying drawings, in which:

FIG. 1 is a cross-sectional view of a nanostructure semiconductor light emitting device manufactured according to an example embodiment of the present inventive concepts;

FIGS. 2a through 2f are process views illustrating a method of manufacturing the nanostructure semiconductor light emitting device according to an example embodiment of the present inventive concepts;

FIG. 2g illustrates a method of manufacturing a nanocore of a semiconductor light emitting device according to an example embodiment of the present inventive concepts;

FIG. 3 is a view illustrating a light emitting nanostructure of a nanostructure semiconductor light emitting device manufactured according to another example embodiment of the present inventive concepts;

FIG. 4 is a view illustrating a light emitting nanostructure of a nanostructure semiconductor light emitting device manufactured according to another example embodiment of the present inventive concepts;

FIGS. 5 and 6 are cross-sectional views each illustrating a semiconductor light emitting device package in which the nanostructure semiconductor light emitting device manufactured according to an example embodiment of the present inventive concepts is employed;

FIGS. 7 and 8 are views each illustrating an example of a backlight unit in which the nanostructure semiconductor light emitting device manufactured according to an example embodiment of the present inventive concepts is employed;

FIG. 9 is a view illustrating an example of a lighting device in which the nanostructure semiconductor light emitting device manufactured according to an example embodiment of the present inventive concepts is employed; and

FIG. 10 is a view illustrating an example of a headlamp in which the nanostructure semiconductor light emitting device manufactured according to an example embodiment of the present inventive concepts is employed.

### DETAILED DESCRIPTION

Example embodiments of the present inventive concepts will now be described in detail with reference to the accompanying drawings.

Various embodiments will now be described more fully with reference to the accompanying drawings in which some embodiments are shown. The present disclosure may, however, be embodied in different forms and should not be construed as limited to the embodiments set forth herein. Rather, these embodiments are provided so that this disclosure is thorough and complete and fully conveys the present disclosure to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, maybe used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device maybe otherwise oriented (rotated 90 degrees or at other orientations) and the spatially relative descriptors used herein interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an embodiment can be implemented differently, functions or operations described in a particular block may occur in a different way from a flow described in the flowchart. For example, two consecutive blocks may be performed simultaneously, or the blocks may be performed in reverse according to related functions or operations.

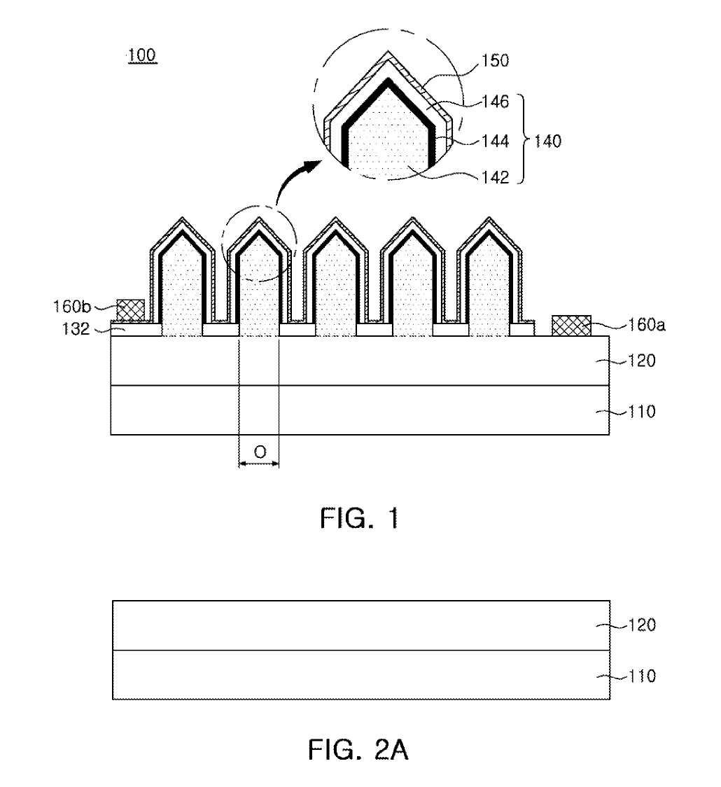

FIG. 1 is a cross-sectional view of a nanostructure semiconductor light emitting device according to an example embodiment of the present inventive concepts.

Referring to FIG. 1, a nanostructure semiconductor light emitting device 100 may include a growth substrate 110, a conductive base layer 120, a first mask layer 132, a plurality of light emitting nanostructures 140, and a contact electrode layer 150. The light emitting nanostructures 140 may include nanocores 142, active layers 144, and first conductivity type semiconductor layers 146. In an example embodiment, the conductive base layer 120 maybe a second conductivity type semiconductor base layer. The conductive base layer 120 may not require a separate growth substrate 110. The nanostructure semiconductor light emitting device 100 may further include first and second electrodes 160a and 160b electrically connected to the contact electrode layer 150 and the conductive base layer 120, respectively. The first electrode 160a may be disposed on an exposed portion of an upper surface of the conductive base layer 120 exposed by removing one side of the nanostructure semiconductor light emitting device 100 so as to partially expose the upper surface of the conductive base layer 120.

The growth substrate 110 may be provided as a substrate for growing the conductive base layer 120. The growth substrate 110 may be formed of an insulating material, a conductive material, or a semiconductor material such as sapphire, SiC, MgAl₂O₄, MgO, LiAlO₂, LiGaO₂, GaN or the like. Sapphire widely used as a nitride semiconductor growth substrate may be a crystal having Hexa-Rhombo R3c symmetry. The sapphire may have a lattice constant of 13.001 Å in a C-axis direction and a lattice constant of 4.758 Å in an A-axis direction and may include a C (0001) plane, an A (11-20) plane, an R (1-102) plane, and the like. In an example embodiment, the C plane is mainly used as a nitride growth substrate because the C plane relatively facilitates the growth of a nitride film and is stable at higher temperatures. A silicon (Si) substrate may be used as the growth substrate 110. The Si substrate appropriate for forming a large diameter and requiring relatively low manufacturing costs may be used, whereby the mass production thereof may be enhanced. In example embodiments using the Si substrate, after a nucleation layer (not shown) formed of a material such as AlₓGa₁₋ₓN (0≦x≦1) is formed on the growth substrate 110, a nitride semiconductor having a desired structure may be grown on the nucleation layer.

The conductive base layer 120 may be disposed on the growth substrate 110. The conductive base layer 120 may be formed of a second conductivity type semiconductor material, for example, a nitride semiconductor satisfying AlₓIn_{y}Ga_{1-x-y}N (0≦x≦1, 0≦y≦1, 0≦x+y≦1). The conductive base layer 120 may be doped with, for example, an n-type impurity such as Si.

In an example embodiment, the conductive base layer 120 may provide a crystal surface for the growth of the nanocores 142 of the light emitting nanostructures 140 and may be connected to each of the light emitting nanostructures 140, thereby serving as a contact electrode layer.

The first mask layer 132 may be disposed on the conductive base layer 120. The first mask layer 132 may be formed of a material generally usable in selective growth, such as a silicon oxide, a silicon nitride or the like. For example, the first mask layer 132 maybe formed of at least one of SiOₓ, SiOₓN_{y}, SiₓN_{y}, Al₂O₃, TiN, AlN, ZrO, TiAlN, and TiSiN. The first mask layer 132 may include a plurality of openings O exposing portions of the conductive base layer 120. Diameters, lengths and positions of the nanocores 142 may be determined depending on sizes of the plurality of openings O. The plurality of openings O may have various shapes such as circular shapes, quadrangular shapes, hexagonal shapes or the like.

The first mask layer 132 may serve to prevent the active layers 144 and the first conductivity type semiconductor layers 146 from being electrically connected to the conductive base layer 120.

The plurality of light emitting nanostructures 140 may be disposed in positions corresponding to the plurality of openings O, respectively. The light emitting nanostructures 140 may have a core-shell structure including the nanocores 142 grown from the conductive base layer 120 exposed through the plurality of openings O, the active layers 144, and the first conductivity type semiconductor layers 146, the active layers 144 and the first conductivity type semiconductor layer 146 being sequentially formed on surfaces of the nanocores 142.

Each of the light emitting nanostructures 140 employed in example embodiments may include a body portion having a hexagonal prismatic structure and an upper end portion positioned on the body portion. Side surfaces of the body portion of the light emitting nanostructure 140 may have the same crystal planes, and the upper end portion of the light emitting nanostructure 140 may have crystal planes different from those of the side surfaces thereof. An upper end portion T of the light emitting nanostructure 140 may have a hexagonal pyramid shape. For example, in example embodiments where a growth surface of the conductive base layer 120 is a c-plane, the side surfaces of the body portion may be non-polar planes m and the surfaces of the upper end portion may be semi-polar planes.

The nanocores 142 and the first conductivity type semiconductor layers 146 may be formed of a second conductivity type semiconductor material and a first conductivity type semiconductor material, respectively. The first and second conductivity type semiconductor materials may be semiconductors doped with an n-type impurity and a p-type impurity, respectively, but are not limited thereto. Conversely, the first and second conductivity type semiconductor materials maybe p-type and n-type semiconductors, respectively.

The nanocores 142 may be nitride semiconductor layers having a composition of InₓGa₁₋ₓN, where x is greater than 0 but smaller than 1, specifically, greater than 0 but smaller than 0.5, more specifically, greater than 0 but smaller than 0.2. In addition, the nanocores 142 may be nitride semiconductors having a composition of AlₓIn_{y}Ga_{1-x-y}N (0≦x<1, 0<y<1, 0<x+y≦1).

The active layers 144 may be disposed on surfaces of the nanocores 142. The active layers 144 may be on a surface of the plurality of the nanocores 142. The active layers 144 may be multi-quantum well (MQW) structures having alternately stacked quantum well layers and quantum barrier layers. For example, in the case of a nitride semiconductor, the active layers 144 may have a multi-quantum well (MQW) structure of In_{y}GaN_{1-y}/GaN or In_{y}GaN_{1-y}/In_{z}GaN_{1-z} (0<y<1, 0<z<1, y>z) . In other example embodiments, the active layers 144 may have a single quantum well (SQW) structure.

The first conductivity type semiconductor layers 146 may be disposed on the surfaces of the active layers 144. The first conductivity type semiconductor layers 146 may be formed of a nitride semiconductor, for example, a material having a composition of AlₓIn_{y}Ga_{1-x-y}N (0≦x≦1, 0≦y≦1, 0≦x+y≦1). Although not specifically illustrated, the first conductivity type semiconductor layers 146 may include an electron blocking layer, and the electron blocking layer may be a p-type AlGaN layer or a p-type InAlGaN layer, but is not limited thereto.

Although not specifically illustrated, a filling layer may be disposed on the first mask layer 132, filling space between the plurality of light emitting nanostructures 140. That is, the filling layer may be disposed between the adjacent light emitting nanostructures 140, thereby serving as a support for the light emitting nanostructures 140 against external pressure.

Although not limited thereto, the filling layer may be formed of an insulating material, for example, one of SiO₂, tetraethyl orthosilicate (TEOS), borophosphosilicate glass (BPSG), spin-on glass (SOG) and spin-on dielectric (SOD).

A height of the filling layer may be lower than those of the light emitting nanostructures 140 so that partial regions of the light emitting nanostructures 140 may not be covered with the filling layer and be exposed. For example, the partially exposed regions of the light emitting nanostructures 140 may include the upper end portions thereof.

The contact electrode layer 150 may be disposed on the first conductivity type semiconductor layers 146 and the first mask layer 132. In example embodiments in which the filling layer is present, the contact electrode layer 150 may be disposed on the first conductivity type semiconductor layers 146 and the filling layer.

The contact electrode layer 150 may be a continuous layer covering all of the first conductivity type semiconductor layers 146 and the second mask layer 130 (the filling layer in example embodiments in which a filling layer exists).

The contact electrode layer 150 may be formed of an ohmic-contact material capable of realizing ohmic-contact with the first conductive type semiconductor layers 146, and for example, may contain at least one of Ag, Ni, Al, Rh, Pd, Ir, Ru, Mg, Zn, Pt and Au. The contact electrode layer 150 may have a single layer structure or a multilayer structure. In addition, the contact electrode layer 150 may be one of a transparent conductive oxide layer or nitride layer, and light emitted from the light emitting nanostructures 140 may penetrate through the contact electrode layer 150. The contact electrode layer 150 having transparent conductivity may be formed of, for example, at least one selected from a group consisting of indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂ or Zn₍₁₋ₓ₎MgₓO (zinc magnesium oxide, 0≦x≦1). In example embodiments, the contact electrode layer 150 may contain graphene.

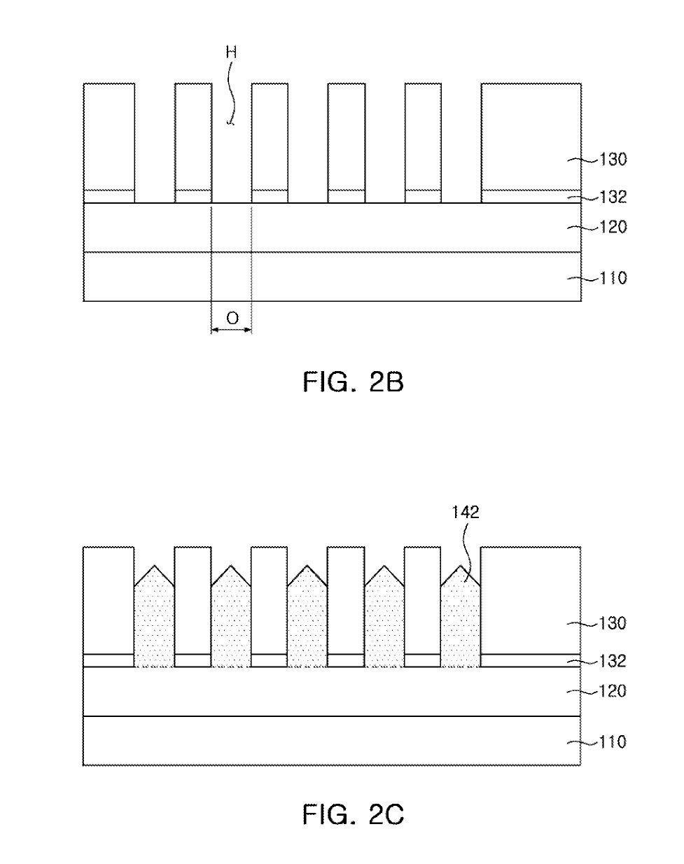

FIGS. 2a through 2f are process views illustrating processes of a method of manufacturing the nanostructure semiconductor light emitting device 100 illustrated in FIG. 1.

Referring to FIG. 2a, the manufacturing method may be initiated with a process of providing the conductive base layer 120 formed of the second conductivity type semiconductor material on the growth substrate 110.

The conductive base layer 120 may not only provide a crystal growth surface for the growth of the light emitting nanostructures 140 but may also be provided as a structure electrically connecting polarities of one sides of the light emitting nanostructures 140 to each other. Thus, the conductive base layer 120 may be formed as a semiconductor single crystal having electrical conductivity. Prior to the growth of the conductive base layer 120, a multilayer structure including a buffer layer configured of AlₓIn_{y}Ga_{1-x-y}N (0≦x≦1, 0≦y≦1, 0≦x+y≦1) may be further formed on the growth substrate 110. The multilayer structure may include intermediate layers formed of undoped GaN layer and AlGaN layer or a combination of the layers in order to reduce or prevent the leakage of a current from the conductive base layer 120 to the buffer layer and/or improve crystal quality of the conductive base layer 120.

The conductive base layer 120 may be grown through a process such as metal organic chemical vapor deposition (MOCVD), hydride vapor phase epitaxy (HYPE), molecular beam epitaxy (MBE), or the like, for example.

Next, as illustrated in FIG. 2b, mask layers having the plurality of openings O may be formed on the conductive base layer 120, and through holes H penetrating through first and second mask layers 132 and 130 may be formed so as to expose portions of the conductive base layer 120.

The mask layers may be obtained by sequentially forming the first mask layer 132 and the second mask layer 130 on the conductive base layer 120. The first mask layer 132 may be formed of an electrical 14 insulating material and if necessary, the second mask layer 130 may also be formed of an insulating material.

A method of forming the through holes H may be performed by using a dry etching process, for example. Specifically, a plasma etching process may be performed using a gas formed by combining gas such as CF₄, C₂F₆, C₃F₈, C₄F₈, or CHF₃ with at least one of O₂ and Ar.

In example embodiments forming through holes H using a dry etching process, etch selectivity of the first mask layers 132 may be different from that of the second mask layers 130. In other word, the first mask layer 132 may be formed using a material having a lower or a significantly lower etch rate than that of the second mask layer 130 under the same conditions. Accordingly, the first mask layer 132 may be provided as an etch stop layer for the second mask layer 130. For example, the first mask layer 132 may be formed of SiN, and the second mask layer 130 may be formed of SiO₂.

In other example embodiments, such a difference in etch rate may be obtained using a difference in pore density. The difference in etch rates between the first and second mask layers 132 and 130 may be obtained by employing a porous material in the second mask layer 130 or both of the first and second mask layers 132 and 130 and varying a difference in degrees of porosity thereof. In example embodiments, the first and second mask layers 132 and 130 may be formed of the same material. For example, the first mask layer 132 may be formed of SiO₂ having a first porosity and the second mask layer 130 may also be formed of SiO₂; the same material as that of the first mask layer 132, but may have a second porosity greater than the first porosity, whereby the first mask layer 132 may have an etch rate lower than that of the second mask layer 130 under conditions in which the second mask layer 130 is etched

Thicknesses of the first and second mask layers 132 and 130 may be designed in consideration of desired heights of the light emitting nanostructures 140. The thickness of the second mask layer 130 may be greater than that of the first mask layer 132 in order to broaden a surface area of the exposed light emitting nanostructures 140 for high luminous efficiency. For example, the thickness of the first mask layer 132 may be 1 nm to 900 nm, and the thickness of the second mask layer 130 may be 500 nm to 10000 nm.

The sizes of the openings O exposing the surface of the conductive base layer 120 may be designed in consideration of desired sizes of the light emitting nanostructures 140. Planar shapes of the plurality of openings O may be variously implemented such as polygonal shapes, quadrangular shapes, oval shapes or circular shapes, depending on the desired result(s).

Although FIG. 2b illustrates the through hole H having a rod shape, it is not limited thereto. The through hole H may be variously formed by using an appropriate etching process. For example, the through hole H may have a pillar shape in which a width thereof is downwardly reduced or is downwardly increased. The through hole H may have a high aspect ratio. Specifically, the aspect ratio of the through hole H may be equal to or greater than 3:1 and further, may be equal to or greater than 10:1.

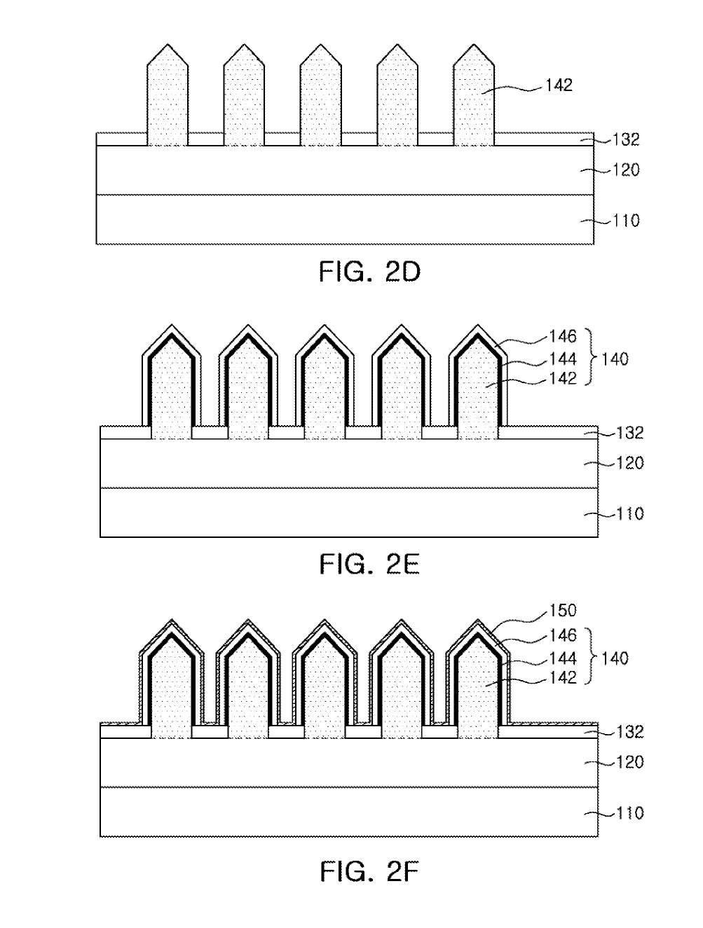

Next, as illustrated in FIG. 2c, the plurality of through holes H (see FIG. 3b) may be filled by growing the first conductivity type semiconductor layers in the openings O (see FIG. 2b) through which the conductive base layer 120 is exposed, thereby forming a plurality of the nanocores 142 having shapes depending on shapes of the through holes H. A method of growing the nanocores may be, for example, a chemical vapor deposition (CVD) method, specifically, a metal organic chemical vapor deposition (MOCVD) method.

FIG. 2g illustrates a method 400 of manufacturing a nanocore of a semiconductor light emitting device according to an example embodiment of the present inventive concepts. As shown in FIG. 2g, a mixed gas atmosphere of nitrogen and hydrogen is provided at S410. Then, at S420 an indium-containing precursor gas is introduced into the mixed gas atmosphere to grow a nanocore 142 through a hole in the conductive base layer 120.

As described above, the nanocores 142 may be nitride semiconductor layers having a composition of InₓGa₁₋ₓN (0<x<1) . In addition, the nanocores 142 may be nitride semiconductors having a composition of AlₓIn_{y}Ga_{1-x-y}N (0≦x<1, 0<y<1, 0<x+y≦1). In order to grow the nanocores 142 having such a composition, a precursor gas containing an indium-containing precursor gas may flow in an atmosphere of mixed gas of nitrogen and hydrogen. Under this condition, the nanocores 142 having a composition of InₓGa₁₋ₓN (0<x<1) or AlₓIn_{y}Ga_{1-x-y}N (0≦x≦1, 0<y<1, 0<x+y≦1) may be grown through the through holes H from the conductive base layer 120.

Since a vapor pressure of indium is higher than that of gallium, the nanocores 142 may be grown at a temperature lower than a temperature at which GaN is grown when the nanocores 142 have a composition of InₓGa₁₋ₓN (0<x<1) . In addition, since hydrogen may prompt the vaporization of indium, the nanocores 142 may be grown in a gas atmosphere not containing hydrogen, for example, in a 100% nitrogen atmosphere.

However, when the nanocores 142 are grown using the mask layers, if the nanocores 142 are grown at low temperature and in 100% nitrogen atmosphere, a speed of migration of indium and gallium on the second mask layer 130 maybe lowered, such that the nanocores 142 may be difficult to grow. If hydrogen gas is added during the growth of the nanocores 142, the speed of migration of indium and gallium on the second mask layer 130 may be increased even at a low temperature. Accordingly, the nanocores 142 may be grown between the first and second mask layers 132 and 130.

The reasons for increasing the content of indium in the nanocores 142 are as follows.

In example embodiments where the content of indium in the quantum well layers of the multi-quantum well structure in the active layers 144 is increased, a level of energy band gap in the quantum well layers may be decreased. Due to the quantum well layers having the decreased level of energy band gap, the active layers 144 with multi-quantum well structure may emit long-wavelength light. However, when the content of indium in the quantum well layers within the active layers 144 is increased, and the nanocores 142 contacting the active layers 144 are nitride semiconductor layers not containing indium, for example, GaN layers, a difference in lattice constants between the nanocores 142 and the quantum well layers within the active layers 144 may be increased. In example embodiments where the difference in lattice constants is increased, dislocations may be generated inside the active layers 144 and luminous efficiency of the light emitting nanostructures 140 may be degraded.

In order to decrease dislocations in the active layer 144 having a high content of indium, a method of growing the nanocores 142 containing indium may be required.

In example embodiments where the nanocores 142 contain indium, the difference in lattice constants between the nanocores 142 and the active layers 144 may be reduced, such that dislocations generated within the active layers 144 may be decreased.

According to an example embodiment, the nanocores containing indium may be manufactured.

According to an example embodiment, in order to grow the nanocores 142 containing indium, hydrogen may be present in the mixed gas of nitrogen and hydrogen in an amount of 0.01 to 0.99. Specifically, hydrogen may be present in the mixed gas of nitrogen and hydrogen in an amount of 0.01 to 0.5. More specifically, hydrogen may be present in the mixed gas of nitrogen and hydrogen in an amount of 0.01 to 0.3.

According to an example embodiment, a growth temperature of the nanocores 142 may be 800° C. to 1050° C., specifically, 820° C. to 1030° C., more specifically, 850° C. to 1000° C.

The indium-containing precursor gas may be, for example, trimethylindium (TMI) gas. In example embodiments where the nanocores 142 are group III nitride-based semiconductor layers, trimethylgallium (TMGa) may be used as a source of a group III element in the precursor gas and ammonia (NH₃) may be used as a source of nitrogen in the precursor gas.

The content of indium within the nanocores 142 may be controlled by a flow rate of trimethylindium precursor gas . In the case that the flow rate of trimethylindium precursor gas is increased, the content of indium within the nanocores 142 may be increased.

FIG. 3 is a view illustrating a light emitting nanostructure 240 of a nanostructure semiconductor light emitting device 200 manufactured according to another example embodiment of the present inventive concepts.

Referring to FIG. 3, the content of indium within a nanocore 242 may be gradually increased upwardly (in an arrow direction) from a lower portion of the nanocore 242. A composition of indium within the nanocore 242 may be changed by gradually increasing a flow rate of the indium-containing precursor gas, gradually decreasing the growth temperature, and/or gradually increasing the content of hydrogen within carrier gas . The content of indium within the nanocore 242 is not limited to that described in example embodiments, and may be gradually decreased, gradually increased and then be decreased, or gradually decreased and then be increased, in an upward direction. The change in the composition of indium may be obtained by gradually changing the flow rate of the indium-containing precursor gas, gradually changing the growth temperature, and/or gradually changing the content of hydrogen within carrier gas . The nanocore 242 in which the content of indium is gradually changed may be more effective in terms of buffering a difference in lattice constants between the conductive base layer 120 and an active layer 244, than a nanocore having a uniform content of indium. Accordingly, dislocations within the active layer 244 may be decreased. A contact electrode layer 250 may be disposed on the light emitting nanostructure 240 including the nanocore 240, the active layer 244, and a first conductivity type semiconductor layer 246.

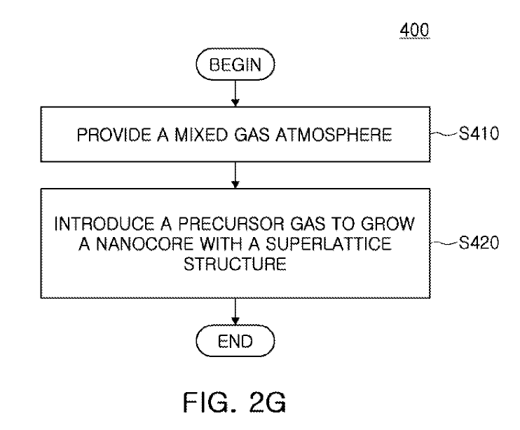

FIG. 4 is a view illustrating a light emitting nanostructure 340 of a nanostructure semiconductor light emitting device 300 manufactured according to another example embodiment of the present inventive concepts.

Referring to FIG. 4, a nanocore 342 may be a superlattice nanocore in which first nanocores 342a having a composition of InₓGa₁₋ₓN (0≦x<1) and second nanocores 342b having a composition of In_{y}Ga_{1-y}N (0≦y≦1) are alternately and repeatedly stacked, where y≠x may be satisfied. A thickness of each of the first nanocores 342a and the second nanocores 342b may be smaller than a critical thickness. The first nanocores 342a and the second nanocores 342b respectively having the thickness smaller than a critical thickness may be alternately stacked, whereby a nanocore 342 may be grown without the occurrence of dislocations.

The first nanocores 342a having the composition of InₓGa₁₋ₓN (0≦x<1) may be grown under the same conditions as those of the first nanocores 142 of FIG. 1. In the composition of InₓGa₁₋ₓN, x may be, specifically, equal to or greater than 0 and equal to or less than 0.5, more specifically, equal to or greater than 0 and equal to or less than 0.2.

The second nanocores 342b having the composition of In_{y}Ga_{1-y}N (0≦y≦1) maybe grown under the same conditions as those of the first nanocores 142 of FIG. 1. In the composition of In_{y}Ga_{1-y}N, y may be, specifically, equal to or greater than 0 and equal to or less than 0.5, more specifically, equal to or greater than 0 and equal to or less than 0.2.

The thickness of each of the first nanocores 342a and the second nanocores 342b may be smaller than the critical thickness causing dislocations. Accordingly, dislocations within an active layer 344 may be decreased. A contact electrode layer 350 may be disposed on the light emitting nanostructure 340 including a nanocore 342, an active layer 344, and a first conductivity type semiconductor layer 346.

Referring to FIG. 2d again, after growing the nanocores 142 through the through holes H, the second mask layer 130 (see FIG. 2c) may be removed so as to partially expose side surfaces of the nanocores 142.

In example embodiments, an etching process capable of selectively removing the second mask layer 130 maybe used, whereby only the second mask layer 130 may be removed and the first mask layer 132 may remain. The remaining first mask layer 132 may reduce or prevent the active layers 144 (see FIG. 1) and the first conductivity type semiconductor layers 146 (see FIG. 1) from being electrically connected to the conductive base layer 120 in a subsequent growth process.

Referring to FIG. 2e, the active layers 144 and the first conductivity type semiconductor layers 146 may be sequentially grown on surfaces of the plurality of nanocores 142. After the growth, the light emitting nanostructures 140 may have the core-shell structure including the nanocores 142, the active layers 144, and the first conductive type semiconductor layers 146.

Then, as illustrated in FIG. 2f, the contact electrode layer 150 may be grown on the plurality of light emitting nanostructures 140 and the first mask layer 132. The contact electrode layer 150 may be formed by, for example, chemical vapor deposition (CVD) or physical vapor deposition (PVD).

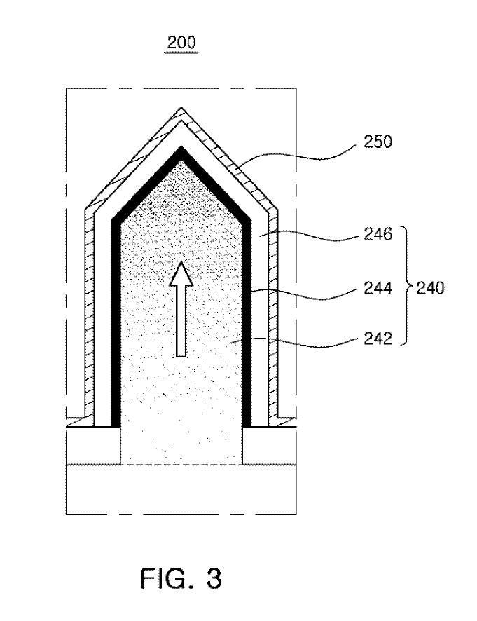

FIG. 5 illustrates a semiconductor light emitting device package 1000 in which the nanostructure semiconductor light emitting device 100 illustrated in FIG. 1 is mounted in a flip chip configuration.

Referring to FIG. 5, the nanostructure semiconductor light emitting device 100 may be mounted on lead frames 1006 and respective electrodes thereof may be electrically connected to the lead frames 1006. If necessary, the nanostructure semiconductor light emitting device 100 may be mounted on another portion of the package 1000 rather than the lead frames 1006, for example, on a package body 1002. The package body 1002 may have a cup shape in order to improve light reflection efficiency, and such a reflective cup may be provided with a sealing part 1004 containing a light transmissive material in order to encapsulate the nanostructure semiconductor light emitting device 100.

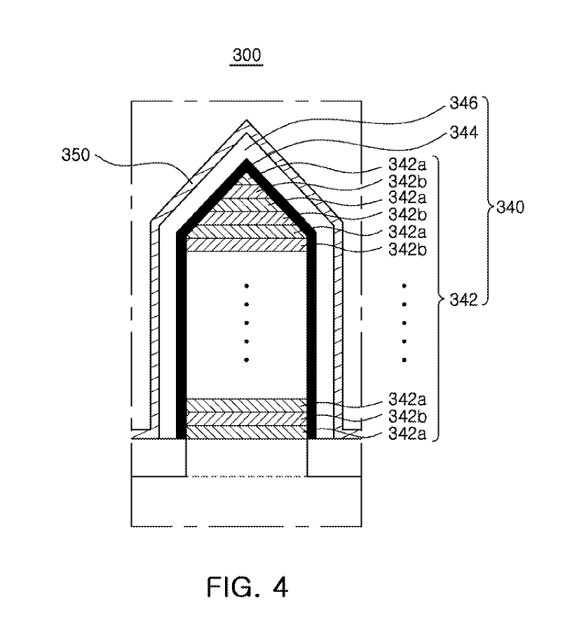

FIG. 6 illustrates a semiconductor light emitting device package 2000 in which a nanostructure semiconductor light emitting device according to an example embodiment of the present inventive concepts is mounted in a flip chip configuration.

Referring to FIG. 6, a nanostructure semiconductor light emitting device 100 (see FIG. 1) may be mounted on a mounting board 2010 and be electrically connected thereto through a wire W.

The mounting board 2010 may include a substrate body 2002, an upper surface electrode 2003 and a lower surface electrode 2004, and a through electrode 2001 connecting the upper surface electrode 2003 and the lower surface electrode 2004 to each other. The mounting board 2010 may be provided as a board such as a PCB, an MCPCB, an MPCB, an FPCB or the like and a structure thereof may be used in various ways.

The sealing part 2005 may have a convex lens shape in which an upper surface thereof is upwardly convex, but may have a concave or convex lens shape according to example embodiments, whereby an orientation angle of light emitted through an upper surface of the sealing part 2005 may be controlled. If necessary, a wavelength conversion material such as phosphors or quantum dots may be disposed on a surface of the sealing part 2005 or the nanostructure semiconductor light emitting device 100 (see FIG. 1).

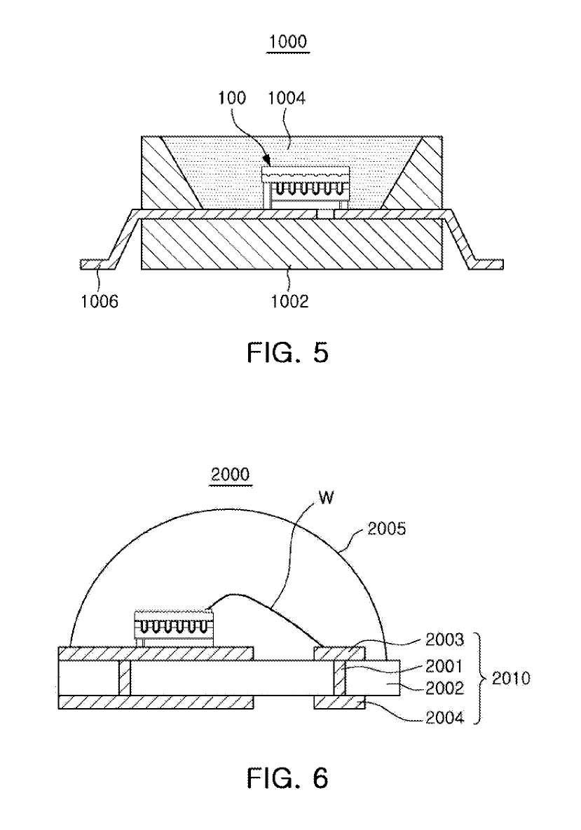

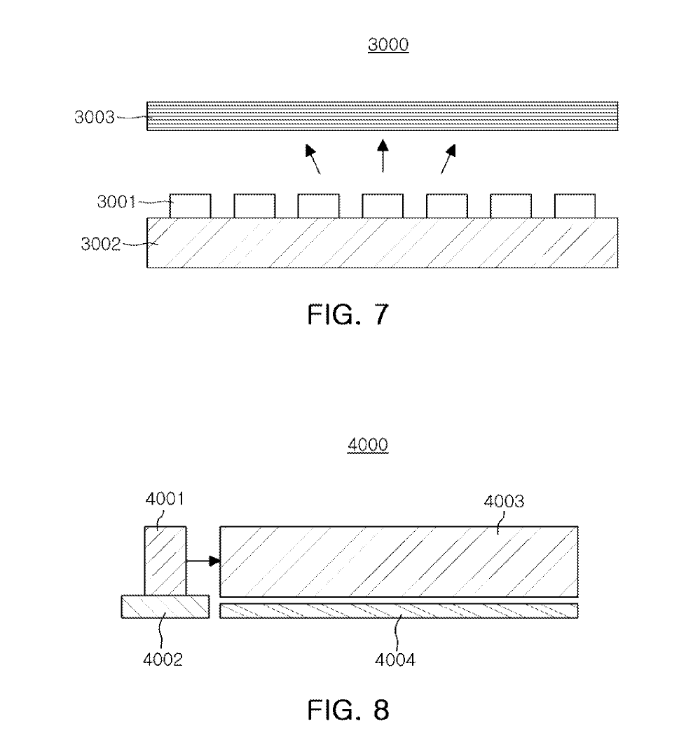

FIGS. 7 and 8 are views each illustrating an example of a backlight unit in which the nanostructure semiconductor light emitting device according to an example embodiment of the present inventive concepts is employed.

Referring to FIG. 7, a backlight unit 3000 may include a light source 3001 mounted on a substrate 3002 and at least one optical sheet 3003 disposed thereabove. The light source 3001 may be the nanostructure semiconductor light emitting device as described above or a package including the nanostructure semiconductor light emitting device.

The light source 3001 in the backlight unit 3000 of FIG. 7 emits light toward a liquid crystal display (LCD) device disposed thereabove. On the other hand, a light source 4001 mounted on a substrate 4002 in a backlight unit 4000 according to another example embodiment illustrated in FIG. 8 emits light laterally, and the emitted light may be incident to a light guide plate 4003 and may be converted into the form of a surface light source. Light having passed through the light guide plate 4003 may be emitted upwardly and a reflective layer 4004 may be disposed under a bottom surface of the light guide plate 4003 in order to improve light extraction efficiency.

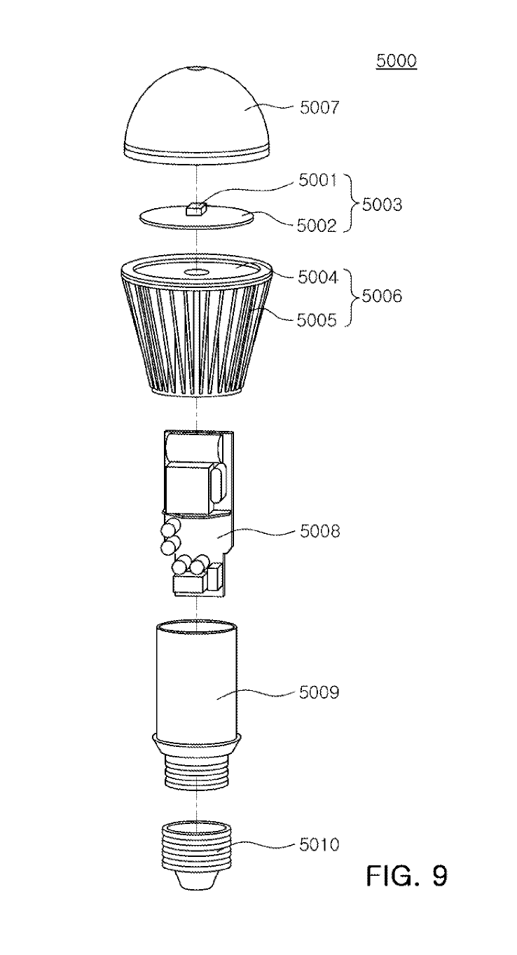

FIG. 9 is an exploded perspective view illustrating an example of a lighting device in which the nanostructure semiconductor light emitting device according to an example embodiment of the present inventive concepts is employed.

Referring to FIG. 9, a lighting device 5000 is exemplified as a bulb-type lamp and may include a light emitting module 5003, a driving unit 5008, and an external connector unit 5010.

In addition, exterior structures such as an external housing 5006, an internal housing 5009, a cover unit 5007 and the like may be additionally included. The light emitting module 5003 may include a light source 5001, which may be the nanostructure semiconductor light emitting device as described above or a package including the nanostructure semiconductor light emitting device, and a circuit board 5002 having the light source 5001 mounted thereon. For example, the first and second electrodes of the nanostructure semiconductor light emitting device may be electrically connected to electrode patterns of the circuit board 5002. The embodiment illustrates a case in which a single light source 5001 is mounted on the circuit board 5002; however, if necessary, a plurality of light sources may be mounted thereon.

The external housing 5006 may serve as a heat radiating part, and include a heat sink plate 3004 in direct contact with the light emitting module 5003 to improve the dissipation of heat and heat radiating fins 5005 covering a lateral surface of the lighting device 5000. The cover unit 5007 may be disposed above the light emitting module 5003 and may have a convex lens shape. The driving unit 5008 may be disposed inside the internal housing 5009 and may be connected to the external connector unit 5010, such as a socket structure, to thereby receive power from an external power source.

In addition, the driving unit 5008 may convert the received power into a current source appropriate for driving the semiconductor light emitting device 5001 of the light emitting module 5003 and supply the converted current source thereto. For example, the driving unit 5008 may be configured of an AC-DC converter, a rectifying circuit part, or the like.

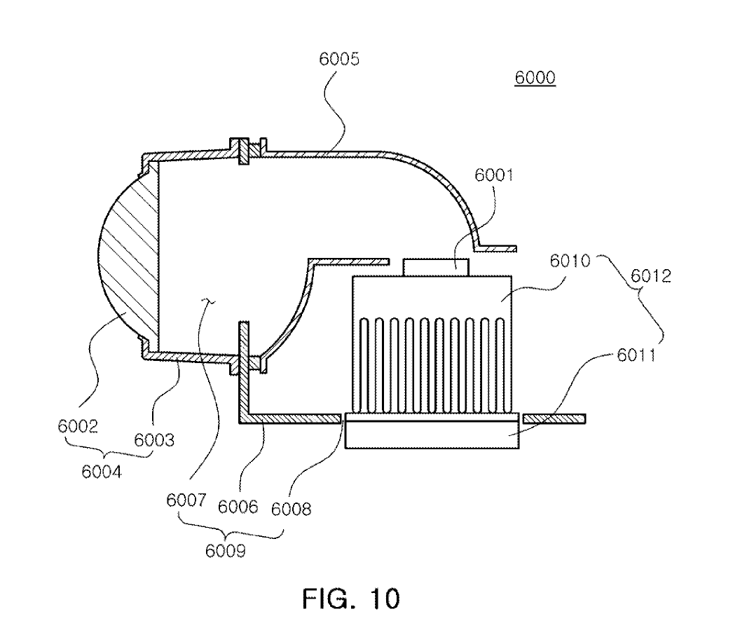

FIG. 10 is a view illustrating an example of a headlamp in which the nanostructure semiconductor light emitting device according to an example embodiment of the present inventive concepts is employed.

Referring to FIG. 10, a headlamp 6000 used as a vehicle lighting element or the like may include a light source 6001, a reflective unit 6005 and a lens cover unit 6004, the lens cover unit 6004 including a hollow guide part 6003 and a lens 6002. The light source 6001 may include the nanostructure semiconductor light emitting device as described above or a package including the nanostructure semiconductor light emitting device.

The headlamp 6000 may further include a heat radiating unit 6012 dissipating heat generated by the light source 6001 outwardly. The heat radiating unit 6012 may include a heat sink 6010 and a cooling fan 6011 in order to effectively dissipate heat. In addition, the headlamp 6000 may further include a housing 6009 allowing the heat radiating unit 6012 and the reflective unit 6005 to be fixed thereto and supported thereby. The housing 6009 may include a support portion 6006 and a central hole 6008 to which the heat radiating unit 6012 is coupled, the central hole 6008 being formed in one surface of the housing 6009.

The other surface of the housing 6009 integrally connected to and bent in a direction perpendicular to the one surface of the housing 6009 may be provided with a forward hole 6007 allowing for the fixation of the reflective unit 6005 in such a manner that the reflective unit 6005 may be disposed above the light source 6001. Accordingly, a forward side may be opened by the reflective unit 6005 and the reflective unit 6005 may be fixed to the housing 6009 such that the opened forward side corresponds to the forward hole 6007, whereby light reflected by the reflective unit 6005 may pass through the forward hole 6007 to thereby be emitted outwardly.

As set forth above, the method of manufacturing the nanostructure semiconductor light emitting device according to example embodiments of the present inventive concepts may have effects of increasing luminous efficiency of the light emitting nanostructure emitting light having a long wavelength.

While example embodiments have been shown and described above, it will be apparent to those skilled in the art that modifications and variations could be made without departing from the scope of the invention as defined by the appended claims.

Additionally, each of the features described above may be combined in any appropriate manner to obtain nanostructure semiconductor light emitting devices, light emitting nanostructures, methods, and/or apparatuses with various combinations of features. In this regard, U.S. application Ser. No. 14/551,978, filed Nov. 24, 2014; Ser. No. 14/723,869, filed May 28, 2015; Ser. No. 13/599,430, filed Aug. 30, 2012; Ser. No. 14/501,232, filed Sep. 30, 2014; U.S. application Ser. No. 14/828,004, filed Aug. 17, 2015; U.S. application Ser. No. 14/833,832, filed Aug. 24, 2015; U.S. application Ser. No. 14/838,322, filed on Aug. 27, 2015, U.S. application Ser. No. 14/838,635, filed on Aug. 28, 2015; and U.S. application Ser. No. 14/867,659, filed on Sep. 28, 2015 are each hereby incorporated by reference in their entirety, thereby disclosing additional nanostructure semiconductor light emitting devices, light emitting nanostructures, methods, and/or apparatuses with various additional combinations of features.

What is claimed is:

1. A method of manufacturing a nanostructure semiconductor light emitting device, the method comprising:
stacking a mask layer on a conductive base layer and forming a through hole penetrating the mask layer;
growing a nanocore through the through hole from the conductive base layer using a precursor gas including an indium-containing precursor gas in an atmosphere of mixed gas of nitrogen and hydrogen;
removing the mask layer; and
sequentially growing an active layer and a first conductivity type semiconductor layer on a surface of the nanocore.

2. The method of claim 1, wherein a temperature growing the nanocore is equal to or greater than 800° C. and equal to or lower than 1050° C.

3. The method of claim 1, wherein volume rate of the mixture gas of nitrogen and hydrogen is 1:0.01 to 1:0.03.

4. The method of claim 1, wherein the mask layer includes a first mask layer on the conductive base layer and a second mask layer on the first mask layer, a thickness of the second mask layer being greater than a thickness of the first mask layer.

5. The method of claim 4, wherein an etch selectivity of the first mask layers is different from an etch selectivity of the second mask layer.

6. The method of claim 1, wherein a flow rate of the indium-containing precursor gas is gradually increased.

7. The method of claim 1, wherein a flow rate of the indium-containing precursor gas is gradually decreased.

8. The method of claim 1, wherein the conductive base layer is a second conductivity type semiconductor layer.

9. The method of claim 1, wherein a composition of the nanocore is InₓGa₁₋ₓN (0<x<1).

10. The method of claim 9, wherein an amount of indium within the nanocore increases in an upward direction.

11. The method of claim 9, wherein an amount of indium within the nanocore decreases in an upward direction away from the conductive base layer.

12. The method of claim 9, wherein the active layer is a single quantum well layer or a multiple quantum well layer formed of In_{y}GaN_{1-y}/GaN or In_{y}GaN_{1-y}/In_{z}GaN_{1-z} (0<y<1, 0<z<1, y>z).

13. The method of claim 1, wherein the indium-containing precursor gas is trimethylindium (TMI) gas.

14. The method of claim 9, wherein the conductive base layer is an n-type GaN layer and the first conductivity type semiconductor layer is a p-type GaN layer.

15. A method of manufacturing a nanostructure semiconductor light emitting device, the method comprising:
stacking a mask layer on a conductive base layer and forming a through hole penetrating the mask layer;
growing a superlattice nanocore through the through hole from the conductive base layer by alternately repeating a process of growing first nanocores of InₓGa₁₋ₓN (0≦x<1) and a process of growing second nanocores of In_{y}Ga_{1-y}N (0≦y≦1), using an precursor gas including trimethylindium (TMI) gas in an atmosphere of mixed gas of nitrogen and hydrogen, wherein y≠x;
removing the mask layer; and
sequentially growing an active layer and a first conductivity type semiconductor layer on a surface of the superlattice nanocore.

16. A method of manufacturing a nanocore of a nanostructure, the method comprising:
providing a mixed gas atmosphere of nitrogen and hydrogen; and
introducing an indium-containing precursor gas to the mixed gas atmosphere to grow a nanocore through a hole in a conductive base layer.

17. The method of claim 16, wherein volume rate of the mixture gas atmosphere of nitrogen and hydrogen is 1:0.01 to 1:0.03.

18. The method of claim 16, wherein the nanocore is grown at a temperature of 800° C. to 1050° C.

19. The method of claim 16, wherein the nanocore has a superlattice structure.

20. The method of claim 16, wherein the nanocore has a composition of InxGa1-xN (0<x<1) or AlxInyGa1-x−yN (0≦x≦1, 0<y<1, 0<x+y≦1).
